(19) United States
(12) Patent Application Publication
(10) Pub. No.: US 2006/0102965 A1
(43) Pub. Date: May 18, 2006

(54) Semiconductor device

(76) Inventors: Sanae Ito, Yokohama-shi (JP); Masaki Kondo, Kawasaki-shi (JP); Hirotaka Amakawa, Kamakura-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/083,295

(22) Filed: Mar. 18, 2005

(30) Foreign Application Priority Data
Nov. 12, 2004 (JP) 2004-328845

(51) Int. Cl. H01L 27/01

(52) U.S. Cl. 257/390

(57) ABSTRACT

There is provided a semiconductor device which includes a projecting semiconductor layer provided on a substrate and having a first side surface and a second side surface opposed to the first side surface, a first gate insulating film provided on the semiconductor layer, a first gate electrode provided on the first gate insulating film, a first and a second diffusion layers provided on respective sides of the first gate electrode and in the semiconductor layer, a first insulating film provided on the first side surface, and a first conductive layer electrically connected to the first gate electrode and provided below the first and second diffusion layers and on a side surface of the first insulating film.

### CROSS-REFERENCE TO RELATED APPLICATIONS

This application is based upon and claims the benefit of priority from prior Japanese Patent Application No. 2004-328845, filed Nov. 12, 2004, the entire contents of which are incorporated herein by reference.

### BACKGROUND OF THE INVENTION

1. Field of the Invention

The present invention relates to a semiconductor device, in particular, a semiconductor device which reduces soft errors.

2. Description of the Related Art

In SRAMs (Static Random Access Memory) and DRAMs (Dynamic Random Access Memory), which are kinds of semiconductor memory devices, it is well known that a phenomenon occurs in which stored data is naturally broken. This phenomenon is called “soft error”.

As causes for soft errors, known are α rays emitted from radioactive substances contained in materials, such as solder, used for semiconductor devices, and fast neutrons traveling as cosmic rays.

Soft errors caused by α rays can be prevented by reducing radioactive substances contained in semiconductor devices, and by taking measures to deal with α rays made incident from above the semiconductor devices. Therefore, it is possible to avoid soft errors by designing the semiconductor device to have a structure in which data is not broken due to incident α rays. Further, the absolute amount of electron-hole pairs generated by soft errors due to α rays is smaller than that of electron-hole pairs generated by soft errors due to fast neutrons. Therefore, soft errors due to α rays can be easily avoided also in this respect.

In the meantime, with respect to soft errors caused by fast neutrons, semiconductor devices are hardly affected by passage of fast neutrons themselves through Si (silicon). However, if a fast neutron collides with an Si atom in a semiconductor device and nuclear fragmentation occurs, a problem is caused in which secondary particles that have less atomic number than the collided Si atom are discharged, and electron-hole pairs are generated along the trajectory of the secondary particles.

Specifically, when the secondary particles penetrate PN junctions of a semiconductor device or passes nearby PN junctions, electron-hole pairs generated along the trajectory of the secondary particles move under the influence of bias applied to the PN junction, in the same manner as in soft errors caused by α rays. Consequently, the electron-hole pairs serve as noise current, and cause the device to malfunction. Such a problem is serious, since the absolute quantity of electron-hole pairs generated in this process are greater by order than that in soft errors caused by α rays, as described above.

As a technique relevant to this, disclosed is a technique of improving resistance to soft errors by increasing the capacity of memory capacitors of DRAM cells (refer to Jpn. Pat. Appln. KOKAI Pub. No. 7-14985).

### BRIEF SUMMARY OF THE INVENTION

A semiconductor device according to a first aspect of the present invention comprises: a projecting semiconductor layer provided on a substrate, and having a first side surface and a second side surface opposed to the first side surface; a first gate insulating film provided on the semiconductor layer; a first gate electrode provided on the first gate insulating film; a first and a second diffusion layers provided on respective sides of the first gate electrode and in the semiconductor layer; a first insulating film provided on the first side surface; and a first conductive layer electrically connected to the first gate electrode, and provided below the first and second diffusion layers and on a side surface of the first insulating film.

A semiconductor device according to a second aspect of the present invention comprises: a first and a second bit lines; and a memory cell connected to the first and second bit lines via a first and a second selective transistors, respectively, the memory cell including a first inverter circuit having a first input terminal and a first output terminal and a second inverter circuit having a second input terminal and a second output terminal, the first inverter circuit including a first P-type MISFET (Metal Insulator Semiconductor Field Effect Transistor) and a first N-type MISFET which are connected in series, the second inverter circuit including a second P-type MISFET and a second N-type MISFET which are connected in series, the first input terminal being connected to the second output terminal, the first output terminal being connected to the second input terminal, each of the first and second N-type MISFETs including: a projecting semiconductor layer provided on a substrate, and having a first side surface and a second side surface opposed to the first side surface; a first gate insulating film provided on the semiconductor layer; a first gate electrode provided on the first gate insulating film; a first and a second diffusion layers provided on respective sides of the first gate electrode and in the semiconductor layer; a first insulating film provided on the first side surface; and a first conductive layer electrically connected to the first gate electrode, and provided below the first and second diffusion layers and on a side surface of the first insulating film.

A semiconductor device according to a third aspect of the present invention comprises: a first and a second bit lines; and a memory cell connected to the first and second bit lines via a first and a second selective transistors, respectively, the memory cell including a first inverter circuit having a first input terminal and a first output terminal and a second inverter circuit having a second input terminal and a second output terminal, the first inverter circuit including a first P-type MISFET and a first N-type MISFET which are connected in series, the second inverter circuit including a second P-type MISFET and a second N-type MISFET which are connected in series, the first input terminal being connected to the second output terminal, the first output terminal being connected to the second input terminal, each of the MISFETs including: a projecting semiconductor layer provided on a substrate, and having a first side surface and a second side surface opposed to the first side surface; a first gate insulating film provided on the semiconductor layer; a first gate electrode provided on the first gate insulating film; a first and a second diffusion layers provided on respective sides of the first gate electrode and in the semiconductor layer; a first insulating film provided on the first side surface; and a first conductive layer electrically connected to the first gate electrode, and provided below the first and second diffusion layers and on a side surface of the first insulating film.

### BRIEF DESCRIPTION OF THE SEVERAL VIEWS OF THE DRAWING

FIG. 1 is a perspective view illustrating a structure of a semiconductor device according to a first embodiment of the present invention.

FIG. 2 is a plan view of the semiconductor device shown in FIG. 1.

FIG. 3 is a cross-sectional view taken along line III-III shown in FIG. 2.

FIG. 4 is a cross-sectional view taken along line IV-IV shown in FIG. 2.

FIG. 5 is a cross-sectional view taken along line V-V shown in FIG. 2.

FIG. 6 is a cross-sectional view taken along line VI-VI shown in FIG. 2.

FIG. 7 is a perspective view illustrating a structure of a semiconductor device according to a second embodiment of the present invention.

FIG. 8 is a plan view of the semiconductor device shown in FIG. 7.

FIG. 9 is a cross-sectional view taken along line IX-IX shown in FIG. 8.

FIG. 10 is a cross-sectional view taken along line X-X shown in FIG. 8.

FIG. 11 is a cross-sectional view illustrating a structure of a semiconductor device according to a third embodiment of the present invention.

FIG. 12 is a circuit diagram illustrating a structure of a main part of an SRAM according to a fourth embodiment of the present invention.

### DETAILED DESCRIPTION OF THE INVENTION

Embodiments of the present invention will now be explained with reference to drawings. In the following explanations, constituent elements having like functions and structures are denoted by like reference numerals, and explanations thereof are repeated, only if necessary.

### First Embodiment

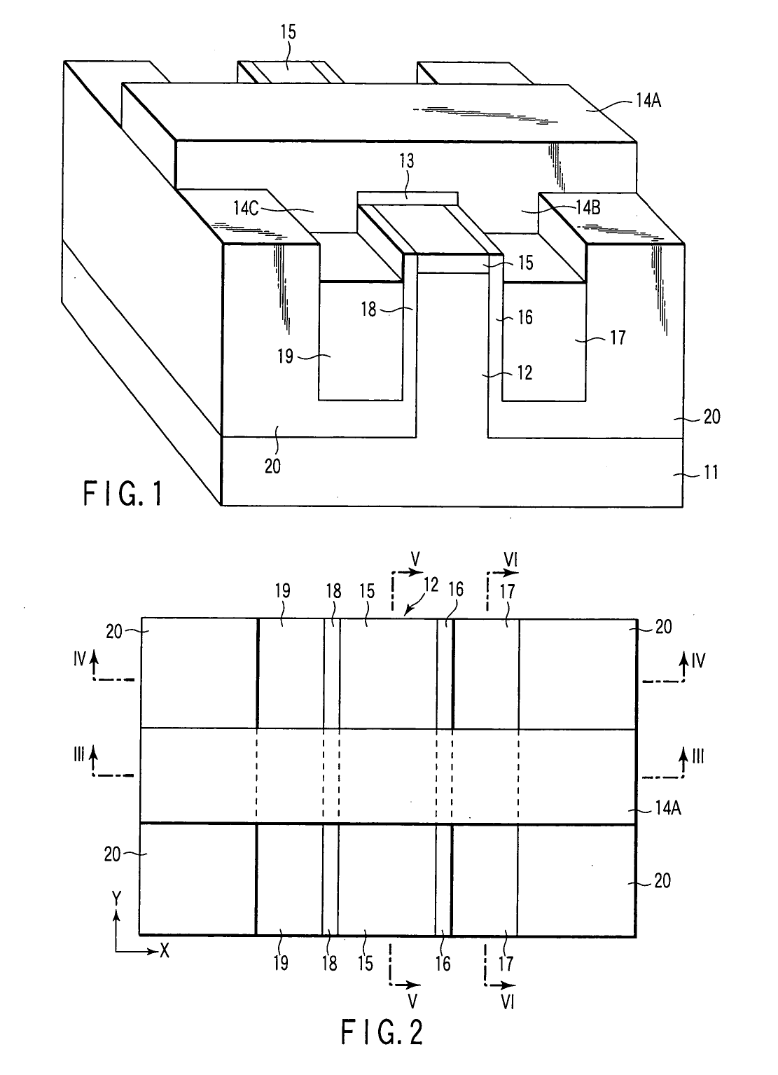

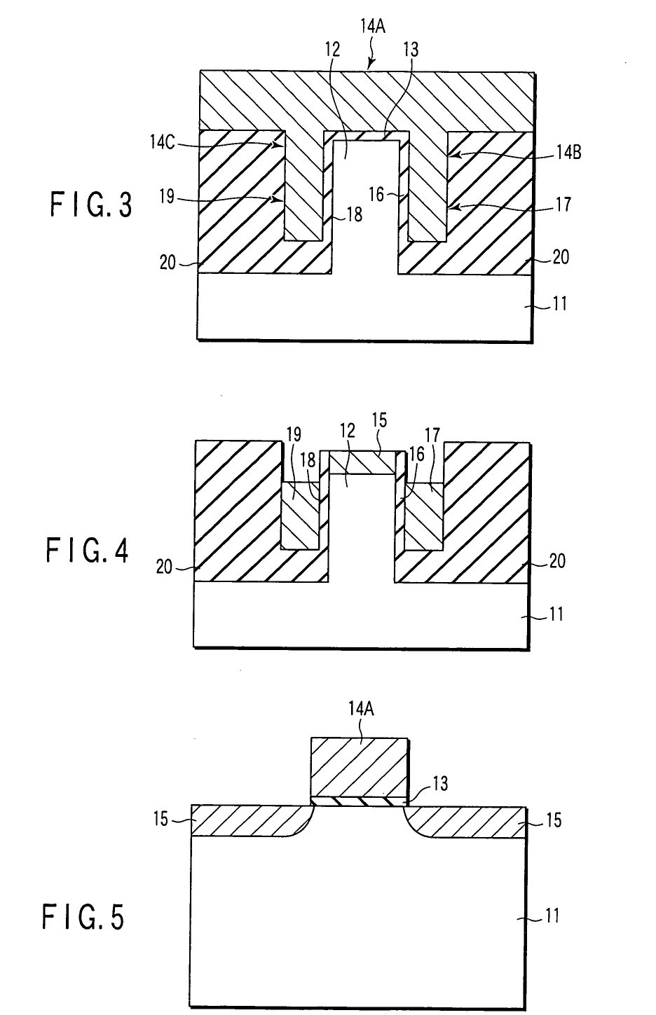

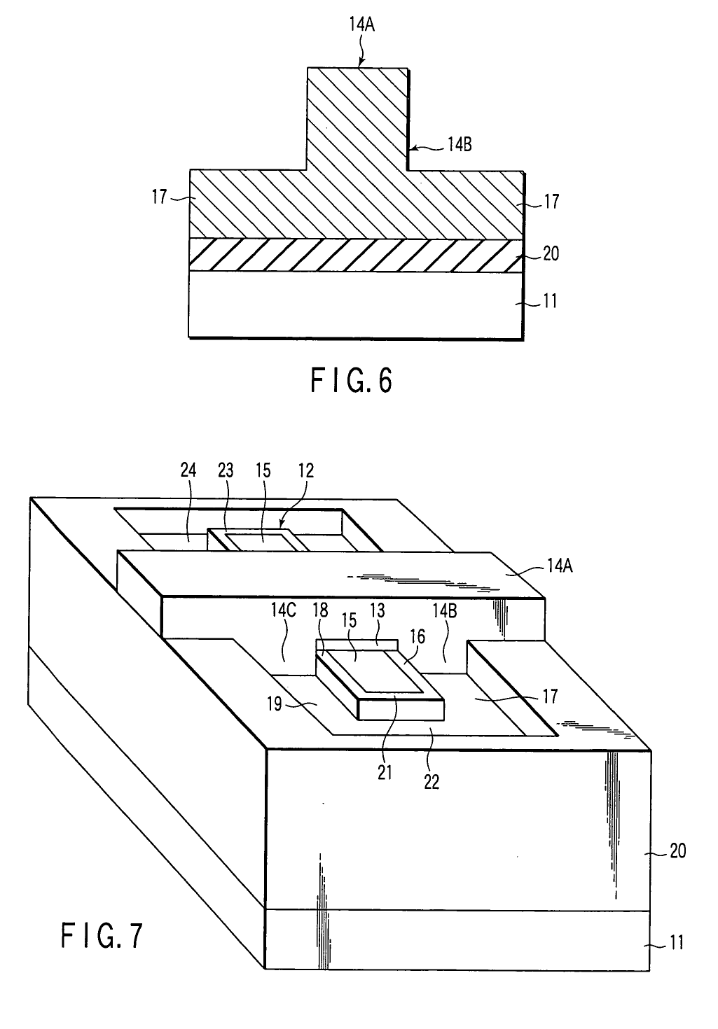

FIG. 1 is a perspective view illustrating a structure of a semiconductor device according to a first embodiment of the present invention. FIG. 2 is a plan view of the semiconductor device shown in FIG. 1. FIG. 3 is a cross-sectional view taken along line III-III shown in FIG. 2. FIG. 4 is a cross-sectional view taken along line IV-IV shown in FIG. 2. FIG. 5 is a cross-sectional view taken along line V-V shown in FIG. 2. FIG. 6 is a cross-sectional view taken along line VI-VI shown in FIG. 2.

A projecting semiconductor layer 12 is formed on a semiconductor substrate 11 formed of, for example, Si (silicon). The projecting semiconductor layer 12 is formed of the same material as that of the semiconductor 11, for example.

A gate insulating film 13 formed of SiO₂ or the like is formed on the projecting semiconductor layer 12. A gate electrode 14A is formed on the gate insulating film 13. Although a gate cap insulating film is formed on a top surface of the gate electrode 14a and sidewall insulating films are formed on both side surfaces of the gate electrode 14A, these are not important in the gist of the present invention and are not shown.

Source/drain regions 15 are formed in the projecting semiconductor layer 12 on both sides of the gate electrode 14A. The source/drain regions 15 are formed by, for example, injecting impurities of high concentration into the top surface of the projecting semiconductor layer 12. By the above method, a MOSFET (Metal Oxide Semiconductor Field Effect Transistor) is formed in the projecting semiconductor layer 12.

An insulating film 16 is formed on one side surface of the projecting semiconductor layer 12. Specifically, the insulating film 16 is formed to cover the whole one side surface of the projecting semiconductor layer 12.

A conductive layer 17 is formed to be lower than the bottom of the source/drain regions 15 and on the side surface of the insulating film 16. On the other side surface of the projecting semiconductor layer 12, an insulating film 18 and a conductive layer 19 are formed in the same manner as the insulating film 16 and the conductive layer 17, respectively.

The insulating films 16 and 18 are formed of the same material as that of the gate insulating film 13. Further, the insulating films 16 and 18 have almost the same thickness as that of the gate insulating film 13.

Each of the conductive layers 17 and 19 has a length almost equal to or greater than the distance from one end to the other end of the two source/drain regions 15 in the Y direction (that is, a direction perpendicular to a direction in which the gate electrode 14A extends) corresponding to a channel length direction. Further, the conductive layers 17 and 19 are formed of the same material as that of the gate electrode 14A. The gate electrode 14A and the conductive layers 17 and 19 are formed of the following materials, for example.

If the MOSFET is of N-type, the gate electrode 14A and the conductive layers 17 and 19 are formed of polycrystalline Si doped with N-type impurities. If the MOSFET is of P-type, the gate electrode 14A and the conductive layers 17 and 19 are formed of polycrystalline Si doped with P-type impurities.

The gate electrode 14A and the conductive layers 17 and 19 are not limited to polycrystalline Si films doped with impurities, but may be metal films, a stacked gate structure comprising a polycrystalline Si film and a metal film (a so-called polymetallic structure), or a stacked gate structure comprising a polycrystalline Si film and a silicide film (a so-called polycide structure), etc.

Examples of the metal film are a TiN film, a W film, a WN film, an Ru film, an Ir film, and an Al film, etc. Examples of the silicide film are a CoSi₂ film, and a TiSi₂ film, etc.

A side gate electrode 14B is formed between the gate electrode 14A and the conductive layer 17 to electrically connect the gate electrode 14A and the conductive layer 17. In the same manner, a side gate electrode 14C is formed between the gate electrode 14A and the conductive layer 19 to electrically connect the gate electrode 14A and the conductive layer 19. The side gate electrodes 14B and 14C are formed of the same material as that of the gate electrode 14A.

The side gate electrodes 14B and 14C function as a part of the gate electrode of the MOSFET. Specifically, the MOSFET of the embodiment has a tri-gate structure. This structure increases the drive current of the MOSFET. Further, since a short channel effect can be suppressed even in a shortened gate length, it is possible to scale down the MOSFET.

Furthermore, since the channel controllability of the MOSFET is improved, the MOSFET can perform fast switching. Further, since the area of the gate electrode is large although the mask area is small, it is possible to set a large gate capacity. Thereby, memory information is not easily inverted due to noise or the like.

A device isolation region 20 is formed under the conductive layer 17 and on the side surface of the conductive layer 17 opposite to the side surface on which the insulating film 16 is formed. In the same manner, another device isolation region 20 is formed under the conductive layer 19 and on the side surface of the conductive layer 19 opposite to the side surface on which the insulating film 18 is formed. The device isolation regions 20 are formed of SiO₂ or the like.

Operation of the semiconductor device formed as described above is explained. When radiation is made incident on the semiconductor device, the radiation reacts with atoms (for example, Si) in the semiconductor device and thereby charged particles are generated. Further, electron-hole pairs are generated along the trajectory of the charged particles. The electron-hole pairs move by the influence of bias applied to the PN junctions of the MOSFET, and form a noise current. Examples of the radiation which causes soft errors are α rays, neutron radiation, proton rays, electron rays, positron radiation, γ rays and X rays.

The semiconductor device of the embodiment has the conductive layers 17 and 19 connected to the gate electrode 14A. The conductive layers 17 and 19 have the same potential as that of the gate electrode 14A. Thereby, the potentials of the conductive layers 17 and 19 prevent the electrons or holes from being attracted to the PN junctions.

Specifically, if the MOSFET is of N-type, the embodiment can reduce soft errors due to electrons, when the N-type MOSFET is turned off (that is, when a ground voltage Vss is applied to the gate electrode).

If the MOSFET is of P-type, the embodiment can reduce soft errors due to holes, when the P-type MOSFET is turned off (when a power supply voltage Vdd is applied to the gate electrode).

Further, the conductive layers 17 and 19 serve as barriers against charged particles. Therefore, the layers prevent movement of charged particles, or shorten the range of charged particles. Since this can suppress generation of electron-hole pairs, it is possible to reduce soft errors.

As described above, the length of each of the conductive layers 17 and 19 in the Y direction perpendicular to the extending direction (X direction) of the gate electrode 14A is desirably almost equal to or greater than the length between both ends of the source/drain regions 15 in the Y direction. This structure can effectively block electrons or holes attracted to the PN junctions. However, the effect of the embodiment can be sufficiently obtained even when the length of the conductive layers is smaller than the length between the both ends of the source/drain regions 15.

In this embodiment, the conductive layers 17 and 19 are provided on the both side surfaces of the projecting semiconductor layer 12. However, a conductive layer may be provided on only one side surface of the projecting semiconductor layer 12. Such a structure can prevent entering of a noise current from the side on which the conductive layer is provided. Further, the potential of the one conductive layer can prevent electrons or holes from being attracted to the PN junctions.

A material called “lifetime killer” may be introduced into a part of the projecting semiconductor layer 12 below the source/drain regions 15. Examples of the substance “lifetime killer” are gold and platinum, etc. This structure can prevent electrons or holes from being attracted to the PN junctions.

Further, a material of wide band gap may be introduced into the projecting semiconductor layer 12 below the source/drain regions 15. This structure can prevent electrons or holes from being attracted to the PN junctions.

The conductive layers 17 and 19 are provided in regions in which an STI (Shallow Trench Isolation) for device isolation is generally to be formed. Therefore, it is possible to suppress increase in the area of the semiconductor device caused by providing the conductive layers 17 and 19.

The term “projecting semiconductor layer” in the embodiment means an element projecting from the semiconductor substrate 11. Therefore, the form of the projecting semiconductor layer may be variously modified to improve the property of the MOSFET.

Specifically, in FIG. 2, a width in the X direction of a part of the projecting semiconductor layer on which the gate electrode 14A is disposed is smaller than a width in the X direction of parts of the projecting semiconductor layer on which the respective source/drain regions 15 are formed. This structure can narrow the channel width of the MOSFET, and thus improve the channel controllability of the MOSFET.

Further, since the width in the X direction of each source/drain region 15 is not changed, the size of the source/drain regions 15 is not reduced. Therefore, a contact plug can be easily formed in the source/drain regions 15. Further, it is possible to suppress increase in the resistance of the source/drain regions 15.

### Second Embodiment

A second embodiment has a structure in which source/drain regions of a MOSFET are surrounded by conductive layers to reduce soft errors.

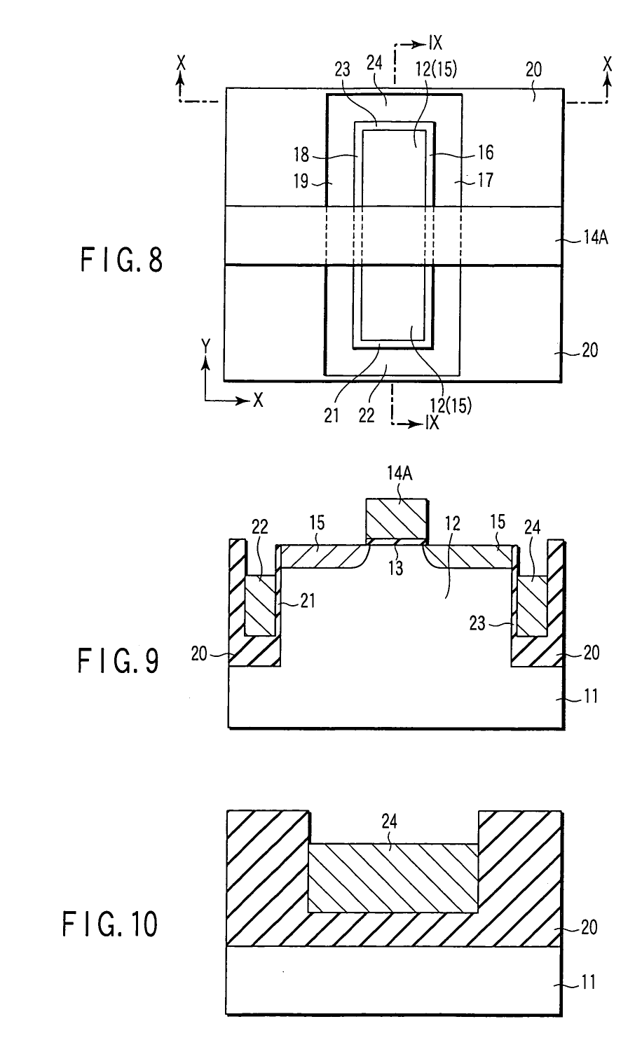

FIG. 7 is a perspective view illustrating a structure of a semiconductor device according to a second embodiment of the present invention. FIG. 8 is a plan view of the semiconductor device shown in FIG. 7. FIG. 9 is a cross-sectional view taken along line IX-IX in FIG. 8. FIG. 10 is a cross-sectional view taken along line X-X in FIG. 8.

A projecting semiconductor layer 12 is formed on a semiconductor substrate 11. Insulating films 21 and 23 are formed on respective side surfaces of the projecting semiconductor layer 12 located on both sides thereof in a Y direction perpendicular to an extending direction (X direction) of a gate electrode 14A. The insulating films 21 and 23 are formed of the same material as that of a gate insulating film 13. Further, the insulating films 21 and 23 have almost the same thickness as that of the gate insulating film 13.

Conductive layers 22 and 24 are formed on respective side surfaces of the insulating films 21 and 23, respectively, to be lower than the bottoms of the source/drain regions 15. The conductive layers 22 and 24 are formed of the same material as that of the gate electrode 14A.

The conductive layer 22 is electrically connected to the gate electrode 14A via a conductive layer 17 and a conductive layer 19. The conductive layer 24 is electrically connected to the gate electrode 14A via a conductive layer 17 and a conductive layer 19. Specifically, each of the conductive layers 22 and 24 has a length in the X direction greater than the width of the source/drain regions 15.

A device isolation region 20 is formed under the conductive layer 22 and on a side surface of the conductive layer 22 opposite to the side surface on which the insulating film 21 is formed. In the same manner, a device isolation region 20 is formed under the conductive layer 24 and on a side surface of the conductive layer 24 opposite to the side surface on which the insulating film 23 is formed.

The semiconductor device having the structure as described above have the conductive layers 22 and 24, and thus can improve the potential controllability of the projecting semiconductor layer 12 more than in the first embodiment. Therefore, it prevents more effectively a noise current caused by electron-hole pairs from flowing into PN junctions.

Further, the conductive layers 22 and 24 serve as barriers against charged particles. This can prevent movement of charged particles or shorten the range of charged particles. Since this can suppress generation of electron-hole pairs, it is possible to reduce soft errors. The other effects of the second embodiment are the same as those of the first embodiment.

In the second embodiment, the conductive layers 22 and 24 are provided on both the Y-direction side surfaces of the projecting semiconductor layer 12. However, a conductive layer may be provided on only one side surface of the projecting semiconductor layer 12. Such a structure can prevent flowing of a noise current into the semiconductor layer from the side on which the conductive layer is provided.

### Third Embodiment

A third embodiment has a structure in which a reverse-tapered semiconductor layer is formed on a semiconductor substrate 11 to prevent electrons or holes generated in the semiconductor layer 11 from entering the semiconductor layer.

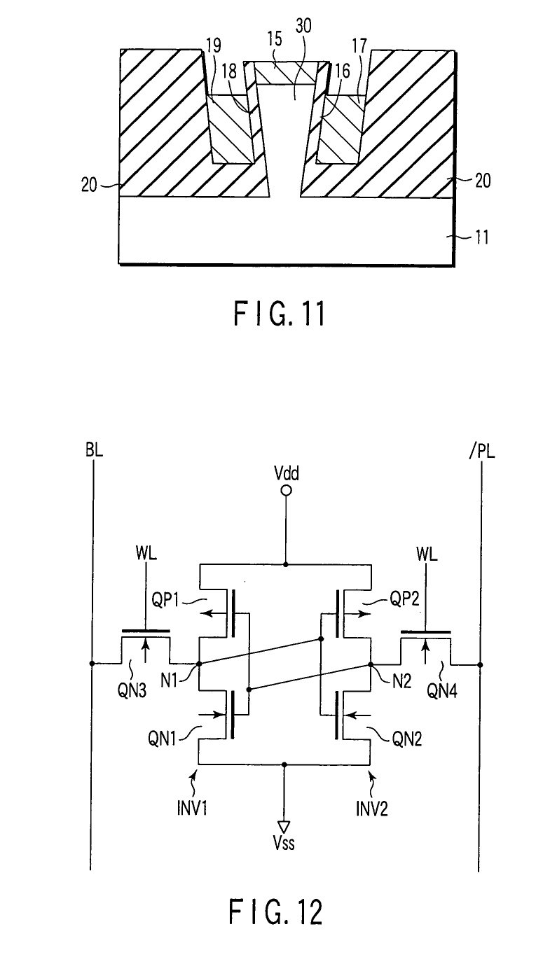

FIG. 11 is a cross-sectional view illustrating a structure of a semiconductor layer according to a third embodiment of the present invention. A plan view thereof is omitted since it is similar to FIG. 2 shown with respect to the first embodiment. FIG. 11 is a cross-sectional view taken along a line in a position corresponding to line IV-IV in FIG. 2.

A reverse-taped semiconductor layer 30 is formed on the semiconductor substrate 11. Specifically, the width in an X direction of the semiconductor layer 30 is gradually narrowed from a top surface of the semiconductor layer 30 toward the semiconductor substrate 11 side. The semiconductor layer 30 is formed of the same material as that of the semiconductor substrate 11.

In the semiconductor layer 30, formed is a MOSFET comprising gate electrodes 14A, 14B and 14C, a gate insulating film 13 and source/drain regions 15.

Further, in the same manner as in the first embodiment, conductive layers 17 and 19 are formed on respective side surfaces of the semiconductor layer 30, via insulating films 16 and 18, respectively. The other parts of the structure of the third embodiment are the same as those of the first embodiment.

In the semiconductor device structured as described above, the width of a lower part of the semiconductor layer 30 is smaller than the width of an upper part thereof. Specifically, the semiconductor layer 30 has a narrowed region through which electrons or holes generated in the semiconductor substrate 11 enter the semiconductor layer 30. This structure prevents electrons or holes generated in the semiconductor substrate 11 from being attracted to the PN junctions. The other effects of the third embodiment are the same as those of the first embodiment.

### Fourth Embodiment

A fourth embodiment is an application of the semiconductor device of the first embodiment to an SRAM.

FIG. 12 is a circuit diagram illustrating a structure of a main part of an SRAM according to the fourth embodiment of the present invention.

The SRAM has a memory cell connected to a bit line pair BL, /BL. The memory cell has two inverter circuits INV1 and INV2. The inverter circuit INV1 comprises a P-type MOSFET QP1 for loading and an N-type MOSFET QN1 for driving. The P-type MOSFET QP1 and the N-type MOSFET QN1 are connected in series between a power supply voltage Vdd and a ground voltage Vss.

Specifically, a source of the P-type MOSFET QP1 is connected to the power supply voltage Vdd. A drain of the P-type MOSFET QP1 is connected to a drain of the N-type MOSFET QN1 via a storage node N1. A source of the N-type MOSFET QN1 is connected to the ground voltage Vss. A gate of the P-type MOSFET QP1 is connected to a gate of the N-type MOSFET QN1.

The storage node N1 corresponds to an output section of the inverter circuit INV1. The gate of the P-type MOSFET QP1 (or the gate of the N-type MOSFET QN1) corresponds to an input section of the inverter circuit INV1.

The inverter circuit INV2 comprises a P-type MOSFET QP2 for loading and an N-type MOSFET QN2 for driving. The P-type MOSFET QP2 and the N-type MOSFET QN2 are connected in series between the power supply voltage Vdd and the ground voltage Vss.

Specifically, a source of the P-type MOSFET QP2 is connected to the power supply voltage Vdd. A drain of the P-type MOSFET QP2 is connected to a drain of the N-type MOSFET QN2 via a storage node N2. A source of the N-type MOSFET QN2 is connected to the ground voltage Vss. A gate of the P-type MOSFET QP2 is connected to a gate of the N-type MOSFET QN2.

The storage node N2 corresponds to an output section of the inverter circuit INV2. The gate of the P-type MOSFET QP2 (or the gate of the N-type MOSFET QN2) corresponds to an input section of the inverter circuit INV2.

The output section of the inverter circuit INV1 is connected to the input section of the inverter circuit INV2. The output section of the inverter circuit INV2 is connected to the input section of the inverter circuit INV1.

The storage node N1 is connected to the bit line BL via an N-type MOSFET QN3 serving as a selective transistor. Specifically, a source of the N-type MOSFET QN3 is connected to the storage node N1. A drain of the N-type MOSFET QN3 is connected to the bit line BL. A gate of the N-type MOSFET QN3 is connected to a word line WL.

The storage node N2 is connected to the bit line /BL via an N-type MOSFET QN4 serving as a selective transistor. Specifically, a source of the N-type MOSFET QN4 is connected to the storage node N2. A drain of the N-type MOSFET QN4 is connected to the bit line /BL. A gate of the N-type MOSFET QN4 is connected to the word line WL.

Each of the N-type MOSFETs QN1 and QN2 for driving is formed of the semiconductor device shown in the first embodiment. Specifically, each of the N-type MOSFETs QN1 and QN2 has conductive layers 17 and 19 connected to a gate electrode, and thereby has a structure which can prevent soft errors.

Operation of the SRAM structured as described above is explained. First, explained is the case where data “1” is transferred to the bit line BL and data “0” is transferred to the bit line /BL, and the word line WL is activated. In this case, the P-type MOSFET QP1 is turned on, and the N-type MOSFET QN1 is turned off.

Therefore, the drain (N-type diffusion layer) of the N-type MOSFET QN1 is supplied with the power supply voltage Vdd. Further, the gate of the N-type MOSFET QN1 is supplied with the ground voltage Vss. This state is vulnerable to soft errors, since no current flows through the channel of the N-type MOSFET QN1.

In this state, electrons generated by the radiation are attracted to the N-type diffusion layer to which the power supply voltage Vdd is supplied. However, the conductive layers 17 and 19 having the same potential as that of the gate prevent the electrons from being collected in the N-type diffusion layer. This reduces soft errors of the SRAM.

Next, explained is the case where data “0” is transferred to the bit line BL and data “1” is transferred to the bit line /BL, and the word line WL is activated. In this case, the P-type MOSFET QP2 is turned on, and the N-type MOSFET QN2 is turned off.

Therefore, the drain (N-type diffusion layer) of the N-type MOSFET QN2 is supplied with the power supply voltage Vdd. Further, the gate of the N-type MOSFET QN2 is supplied with the ground voltage Vss. This state is vulnerable to soft errors, since no current flows through the channel of the N-type MOSFET QN2.

In this state, electrons generated by the radiation are attracted to the N-type diffusion layer to which the power supply voltage Vdd is supplied. However, the conductive layers 17 and 19 having the same potential as that of the gate prevent the electrons from being collected in the N-type diffusion layer. This reduces soft errors of the SRAM.

As described above, the fourth embodiment has a structure in which the N-type MOSFETs in a memory cell of the SRAM prevent soft errors. Thereby, the SRAM has a high resistance to soft errors.

The N-type MOSFETs QN1 and QN2 may be formed of the semiconductor devices shown in the second and third embodiments. Such a structure can obtain the same effect as that of the fourth embodiment.

Further, the P-type MOSFETs QP1 and QP2 may be formed of the semiconductor devices shown in the first to third embodiments. By adopting such a structure, the SRAM has a higher resistance to soft errors.

Although the SRAM is explained in the fourth embodiment, soft errors can be suppressed also in other memories (such as DRAM) using the semiconductor devices (that is, MOSFET) shown in the first to third embodiments.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a projecting semiconductor layer provided on a substrate, and having a first side surface and a second side surface opposed to the first side surface;
a first gate insulating film provided on the semiconductor layer;
a first gate electrode provided on the first gate insulating film;
a first and a second diffusion layers provided on respective sides of the first gate electrode and in the semiconductor layer;
a first insulating film provided on the first side surface; and
a first conductive layer electrically connected to the first gate electrode, and provided below the first and second diffusion layers and on a side surface of the first insulating film.

2. The semiconductor device according to claim 1, wherein a length of the first conductive layer in a channel length direction is greater than a distance, in the channel length direction, from an end of the first diffusion layer on a side more distant from the first gate electrode to an end of the second diffusion layer on a side more distant from the first gate electrode.

3. The semiconductor device according to claim 1, further comprising:
a second insulating film provided on the second side surface; and
a second conductive layer electrically connected to the first gate electrode, and provided below the first and second diffusion layers and on a side surface of the second insulating film.

4. The semiconductor device according to claim 3, wherein a length of the second conductive layer in a channel length direction is greater than a distance, in the channel length direction, from an end of the first diffusion layer on a side more distant from the first gate electrode to an end of the second diffusion layer on a side more distant from the first gate electrode.

5. The semiconductor device according to claim 3, wherein the semiconductor layer has a third side surface perpendicular to the first side surface, and a fourth side surface opposed to the third side surface, and
the semiconductor device further comprises:
a third insulating film provided on the third side surface; and
a third conductive layer connected to the first conductive layer, and provided below the first and second diffusion layers and on a side surface of the third insulating film.

6. The semiconductor device according to claim 5, further comprising:
a fourth insulating film provided on the fourth side surface; and
a fourth conductive layer connected to the first conductive layer, and provided below the first and second diffusion layers and on a side surface of the fourth insulating film.

7. The semiconductor device according to claim 1, further comprising:
a second gate insulating film provided between the first gate electrode and the first conductive layer and on the first side surface; and
a second gate electrode provided on the second gate insulating film, and connected to the first gate electrode and the first conductive layer.

8. The semiconductor device according to claim 3, further comprising:
a third gate insulating film provided between the first gate electrode and the second conductive layer and on the second side surface; and
a third gate electrode provided on the third gate insulating film, and connected to the first gate electrode and the second conductive layer.

9. The semiconductor device according to claim 1, wherein a lower portion of the semiconductor layer is narrower than an upper portion of the semiconductor layer.

10. The semiconductor device according to claim 1, wherein the first conductive layer is formed of the same material as that of the first gate electrode.

11. The semiconductor device according to claim 1, wherein a thickness of the first insulating film is the same as a thickness of the first gate insulating film.

12. The semiconductor device according to claim 1, wherein the first insulating film is formed of the same material as a material of the first gate insulating film.

13. The semiconductor device according to claim 1, wherein the semiconductor layer is of a P type, and the first and second diffusion layers are of an N type.

14. The semiconductor device according to claim 1, wherein the semiconductor layer is of an N type, and the first and second diffusion layers are of a P type.

15. A semiconductor device comprising:
a first and a second bit lines; and
a memory cell connected to the first and second bit lines via a first and a second selective transistors, respectively, the memory cell including a first inverter circuit having a first input terminal and a first output terminal and a second inverter circuit having a second input terminal and a second output terminal, the first inverter circuit including a first P-type MISFET (Metal Insulator Semiconductor Field Effect Transistor) and a first N-type MISFET which are connected in series, the second inverter circuit including a second P-type MISFET and a second N-type MISFET which are connected in series, the first input terminal being connected to the second output terminal, the first output terminal being connected to the second input terminal,
each of the first and second N-type MISFETs including:
a projecting semiconductor layer provided on a substrate, and having a first side surface and a second side surface opposed to the first side surface;
a first gate insulating film provided on the semiconductor layer;
a first gate electrode provided on the first gate insulating film;
a first and a second diffusion layers provided on respective sides of the first gate electrode and in the semiconductor layer;
a first insulating film provided on the first side surface; and
a first conductive layer electrically connected to the first gate electrode, and provided below the first and second diffusion layers and on a side surface of the first insulating film.

16. The semiconductor device according to claim 15, wherein a length of the first conductive layer in a channel length direction is greater than a distance, in the channel length direction, from an end of the first diffusion layer on a side more distant from the first gate electrode to an end of the second diffusion layer on a side more distant from the first gate electrode.

17. The semiconductor device according to claim 15, wherein each of the first and second N-type MISFETs includes:
a second insulating film provided on the second side surface; and
a second conductive layer electrically connected to the first gate electrode, and provided below the first and second diffusion layers and on a side surface of the second insulating film.

18. The semiconductor device according to claim 15, wherein the memory cell is an SRAM (Static Random Access Memory) cell.

19. A semiconductor device comprising:
a first and a second bit lines; and
a memory cell connected to the first and second bit lines via a first and a second selective transistors, respectively, the memory cell including a first inverter circuit having a first input terminal and a first output terminal and a second inverter circuit having a second input terminal and a second output terminal, the first inverter circuit including a first P-type MISFET and a first N-type MISFET which are connected in series, the second inverter circuit including a second P-type MISFET and a second N-type MISFET which are connected in series, the first input terminal being connected to the second output terminal, the first output terminal being connected to the second input terminal,
each of the MISFETs including:
a projecting semiconductor layer provided on a substrate, and having a first side surface and a second side surface opposed to the first side surface;
a first gate insulating film provided on the semiconductor layer;
a first gate electrode provided on the first gate insulating film;
a first and a second diffusion layers provided on respective sides of the first gate electrode and in the semiconductor layer;
a first insulating film provided on the first side surface; and
a first conductive layer electrically connected to the first gate electrode, and provided below the first and second diffusion layers and on a side surface of the first insulating film.

20. The semiconductor device according to claim 19, wherein each of the MISFETs comprises:
a second insulating film provided on the second side surface; and
a second conductive layer electrically connected to the first gate electrode, and provided below the first and second diffusion layers and on a side surface of the second insulating film.
